(19) United States
(12) Patent Application Publication
(10) Pub. No.: US 2024/0288512 A1
(43) Pub. Date: Aug. 29, 2024

(54) Transformer Diagnostics System

(71) Applicant: Hitachi Industrial Equipment Systems Co., Ltd., Chiyoda-ku, Tokyo (JP)

(72) Inventors: Takuya IWASAKI, Tokyo (JP); Haruki MINAGAWA, Tokyo (JP); Akira YAMAGISHI, Tokyo (JP); Ryosuke SUGITA, Tokyo (JP)

(21) Appl. No.: 18/572,335

(22) PCT Filed: Apr. 7, 2022
(86) PCT No.: PCT/JP2022/017216

§ 371 Date: Dec. 20, 2023

(30) Foreign Application Priority Data
Aug. 23, 2021 (JP) 2021-135779

(51) Int. Cl. G01R 31/62; G01R 31/12; H01F 27/32; H01F 27/40

(52) U.S. Cl. CPC G01R 31/62; G01R 31/1263; H01F 27/324; H01F 27/402; H01F 2027/404

(57) ABSTRACT

A transformer diagnostic system having an insulating oil and a winding comprising a detection part detects a temperature at the top and bottom of the insulating oil and hydrogen, an arithmetic unit determines abnormality based on the detected values from the detection part.

### TECHNICAL FIELD

This invention relates to a transformer diagnostic system.

### BACKGROUND ART

As a technique for diagnosing transformer anomalies, patent document 1 uses a temperature sensor at the bottom and moisture content to estimate the degree of polymerization.

The patent document 2 monitors the load factor and other temperature information without incorporating it by means of upper and lower temperature sensors.

The patent document 3 diagnoses deterioration by temperature rise.

### CITATION LIST

### Patent Document

[patent document 1] Japanese unexamined patent publication Tokkai2019-102694

[patent document 2] Japanese unexamined patent publication Tokkaihei5-283240

[Patent document 3] Japanese unexamined patent publication Tokkai2006-24800

### SUMMARY OF THE INVENTION

### Problems to be Solved by the Invention

Since the amount of moisture in oil can vary depending on its temperature, if the moisture content is measured at the bottom of the transformer, the moisture content will be lower than during operation, and the error in the degree of polymerization estimation value may be larger. In patent document 1, where the degree of polymerization is estimated by the temperature sensor at the bottom and the moisture content, the error in the estimated degree of polymerization value may become larger.

There is a time constant between the winding and the oil, and that time constant varies depending on the oil type and winding structure. The temperature rise of the winding is key in considering damage to the insulation paper, and the monitoring of abnormal diagnosis is insufficient in patent document 2, which monitors without incorporating the load factor.

Patent document 3 diagnoses abnormalities mainly by temperature rise, but the parameters that determine the life of the transformer should consider abnormality diagnosis for other factors such as deterioration of insulating oil and the presence or absence of discharge in addition to the deterioration of insulating paper.

The techniques in patent document 1, patent document 2, and patent document 3 are not sufficient to diagnose the lifetime of a transformer with high accuracy.

The purpose of this invention is to provide a transformer diagnostic system that enables highly accurate diagnosis.

One example of this invention is a transformer diagnostic system having an insulating oil and a winding comprising a detection part detects a temperature at the top and bottom of the insulating oil and hydrogen, an arithmetic unit determines abnormality based on the detected values from the detection part.

### Effects of the Invention

According to the present invention, it is possible to realize a diagnostic system for transformer that can perform highly accurate diagnosis.

### BRIEF DESCRIPTION OF DRAWINGS

FIG. 1 This diagram illustrates the transformer and diagnostic system in example 1.

FIG. 2 This figure shows the relationship between winding temperature and oil temperature in example 1.

FIG. 3 This diagram illustrates the transformer and diagnostic system in example 2.

### MODE FOR CARRYING OUT THE INVENTION

The following is an example of the invention, illustrated with drawings.

### Example1

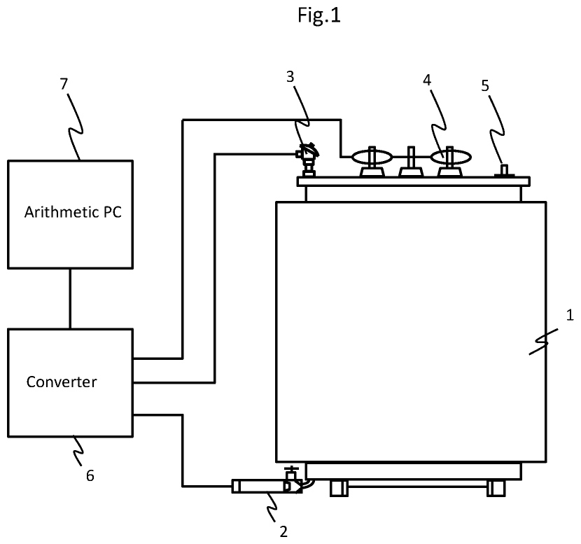

FIG. 1 is a configuration diagram illustrating the transformer and diagnostic system in example 1.

The transformer 1 is an oil-filled transformer with an iron core, a winding attached to the iron core and insulated by insulation paper (winding insulation paper), and insulating oil that soaks the winding and iron core, although the figure is omitted.

Hydrogen detector 2 detects hydrogen gas components based on data from a sensor that detects hydrogen gas components in the insulating oil at the bottom of transformer 1. Here, it is also the detector that detects the temperature in the lower part of the insulating oil of transformer 1. The hydrogen detector and the temperature detector for detecting the temperature at the bottom of the transformer 1 can be separate sensors.

The temperature detector 3 detects temperature based on data from a temperature sensor (such as a resistance thermometer) that detects the temperature at the top of the insulating oil of the transformer 1.

The current detector 4 detects the load current (secondary current) flowing in the load.

Converter 6 performs data conversion of detection data from hydrogen detector 2, temperature detector 3, and current detector 4 for processing on an arithmetic pc (personal computer) 7.

The arithmetic PC 7 (arithmetic section) is a computer device equipped with a processor (processing unit) such as a CPU, main memory, memory device, communication device, etc., and processes various types of information. The processor (processing unit) of the PC 7 executes the operations described below to diagnose abnormalities in the transformer and to predict its service life.

This example transformer diagnostic system comprising a temperature detector 2 that detects hydrogen and the temperature of the bottom part of the insulating oil, a detector 3 that detects the temperature of the top part of the insulating oil, a current detector (CT) 4 that detects the load current (secondary current) flowing in the load, an insulated paper pocket 5 that takes samples of the insulating paper, a converter 6 that converts the data, and an arithmetic PC 7 that performs diagnostics and life prediction of the transformer.

The diagnostic system of the transformer in this example measures the maximum winding temperature at the load factor, upper oil temperature, and lower oil temperature, and acquires the temperature history information by wired or wireless communication with an arithmetic PC 7. At the same time, the arithmetic PC 7 obtains information from the hydrogen sensor and diagnoses abnormalities based on its behavior. The load factor can be calculated from the load current from current detector 4. The current to be detected is not limited to the load current, but the load current can be detected from the primary current of the transformer.

The maximum winding temperature θ_{H} is defined by the following equation 1 (Transformer Reliability Investigation Technical Committee, “Oil-immersed transformer operation guidelines,” IEEJ Technical Report (Part 1) No. 143, November 1986, p. 1-2).

$$\begin{matrix}[ Number 1 ] & \\ {θ}_{H} = {θ}_{a} + {θ}_{0} + {θ}_{g} = {θ}_{a} + {θ}_{0} {N ( \frac{{K}^{2} R + 1}{R + 1} )}^{m} + {θ}_{g} {NK}^{2 n} & ( 1 )\end{matrix}$$

whereas,
θ_{H}: maximum winding temperature (° C.)
θₐ: ambient temperature (° C.) (cooling air or cooling water temperature)
θ₀N: maximum oil temperature rise at rated load (K)
θ_{g}N: Difference between maximum winding temperature and maximum oil temperature at rated load (K)
K: Ratio of actual load P to rated load PN (in this case, load factor)
R: Ratio of load loss to no load loss at rated load (here R=W_{c} (load loss)/Wᵢ (no load loss))
m: Constant determined by the cooling method
n: Constant determined by the cooling method

The parameters in equation 1 that can be directly measured are θₐ and K. The parameters that are transformer-specific and can be specified in the shipment are θ₀N, R, m, and n. Thus, the unknown value is θ_{g}N, and this estimation technique has been defined in various ways.

Many techniques were employed to estimate using pre-measured values, but in the case of new designs, there was a problem that the previous knowledge was not utilized and differed from the results of the pre-measurement.

In this example, the maximum winding temperature can be estimated with high accuracy in addition to estimation by machine learning by analyzing the parameters attributed to them in addition to the actual measurement results.

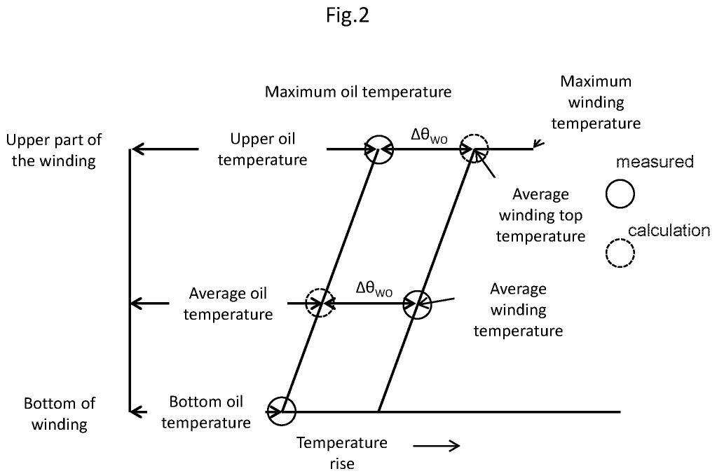

FIG. 2 shows the relationship between winding temperature and insulating oil temperature in example 1.

The vertical axis in FIG. 2 shows the winding height of transformer 1, and the horizontal axis shows the temperature rise of transformer 1.

The solid circled area indicates the area where the temperature is actually measured. Dotted circles indicate areas where temperatures are calculated from the measured temperatures.

The average winding temperature in FIG. 2 can be measured by performing a temperature test before the transformer operation. The maximum oil temperature and the bottom oil temperature can be measured during the operation of the transformer from the temperature detector of the upper insulating oil and the temperature detector of the lower insulating oil, respectively, during operation of the transformer.

The arithmetic PC 7 processor calculates the average oil temperature from the measured upper oil temperature, lower (bottom) oil temperature, and the known winding height, and calculates the “average temperature difference between winding and oil” Δθ_{wo}. from the difference between the measured average winding temperature and the average oil temperature.

The processing unit of arithmetic PC 7 then calculates the “average winding upper temperature” from the measured upper oil temperature (maximum oil temperature) and the “average temperature difference between winding and oil” Δθ_{wo}. The “average winding top temperature” can be calculated from the measured temperatures.

From information such as the “average winding top temperature” and the measured upper oil temperature (maximum oil temperature), the processing unit of the arithmetic PC 7 can accurately estimate the maximum winding temperature.

Until now, the maximum oil temperature of the transformer and the average winding temperature have usually been measured, and the difference between the maximum point oil temperature and the maximum winding temperature was defined as 15° C. Different oil types and designs cause changes in the slope of the winding temperature rise and the slope of the oil temperature rise, resulting in cases where this value cannot be applied as it is.

The processing unit of arithmetic PC 7 in this example measures the oil temperature at the top and bottom, calculates the average oil temperature from the winding height information, and takes the difference from the average winding temperature obtained by actual measurement, so that the aforementioned “difference between the maximum winding temperature at rated load and the maximum oil temperature” θ_{g}N can be defined based on actual measurement rather than a constant 15° C.

The arithmetic PC 7 processor in this example can then calculate the difference θ_{g}N between the maximum oil temperature and the maximum winding temperature according to the slope of the winding temperature rise and the slope of the oil temperature rise for different oil types and designs. The maximum winding temperature : can then be calculated from equation 1 with higher accuracy.

Furthermore, the processing unit of arithmetic PC 7 in this example uses multiple regression curves to estimate the maximum winding temperature from information on various parameters (oil type, capacity, winding height, number of cooling ducts, wire cross-sectional area, wire shape, loss, etc.) determined during design, actual upper oil temperature and lower (bottom) oil temperature, and average winding temperature, using machine the maximum winding temperature is estimated by machine learning. The estimated maximum winding temperature is reflected in the new design to enable highly accurate life prediction at the design stage.

Using the maximum winding temperature obtained above, the arithmetic PC 7 processor in this example predicts the life of the transformer. The life of the transformer is defined as the degradation of the insulation paper and can be approximated by the Arrhenius law using the Montsinger equation within the temperature range of 80° C. to 150° C. and the following equation 2 can be derived by defining it by the 6° C. half rule.

$$\begin{matrix}[ Number 2 ] & \\ \frac{Y}{{Y}_{0}} = {e}^{- 0.1155 ( θ - 95 )} & ( 2 )\end{matrix}$$

whereas,
Y₀: Life expectancy when continuously operated at the highest point temperature of 95° C. (25 to 30 years)
Y: Life span when continuously operated at the highest point temperature θ
θ: maximum point temperature θ (can be defined by maximum winding temperature θ_{H})

The processing unit of the arithmetic PC 7 in this example calculates Y/Y, according to equation 2. Equation 2 allows the remaining life of the transformer to be estimated from the information of the actual thermal history used.

Furthermore, the actual degradation of the insulating paper is also measured by collecting and analyzing a sample of insulating paper from the insulated paper pocket 5 attached to the top of the transformer 1 to measure the average degree of polymerization. If the lifetime estimation does not agree with the analysis results, etc., the average degree of polymerization measured is used as the corrected equation 2, and the processing unit of the arithmetic PC 7 in this example performs the estimation calculation according to the corrected equation. In this way, the system can be doubly monitored by on-line and off-line monitoring. Such a configuration allows a more reliable diagnostic system to be configured.

In this example, a hydrogen detector 2 is installed in the lower part of the tank of the transformer 1 to prevent a serious accident from occurring due to a sudden abnormality such as local heating that is left unnoticed. The processing apparatus of the arithmetic PC 7 diagnoses an abnormality of the transformer by determining that the hydrogen component acquired from the hydrogen detector 2 exceeds a predetermined value (threshold).

Hydrogen is the cause of all abnormal phenomena and exerts its effects on discharge, heating, and deterioration of insulation paper. In some cases, the degradation of insulation paper can be measured using the moisture content in oil as a proxy, but in this case, if the temperature at the time of collection changes, the saturated moisture content in the oil will differ, and the deposited moisture will migrate to the insulation paper, so there is a risk of misjudging the measurement results. On the other hand, in the case of hydrogen, which is a gas, changes in solubility due to changes in temperature exist, but the changes are several times smaller than those of water content, so the accuracy of analysis is dramatically improved.

The above-mentioned transformer detection data is imported into an arithmetic PC 7 through converter 6, and various calculations are performed to determine abnormalities in the transformer and to diagnose its remaining life.

According to this example, it is possible to realize a transformer's diagnostic system that can perform highly accurate diagnosis.

### Example 2

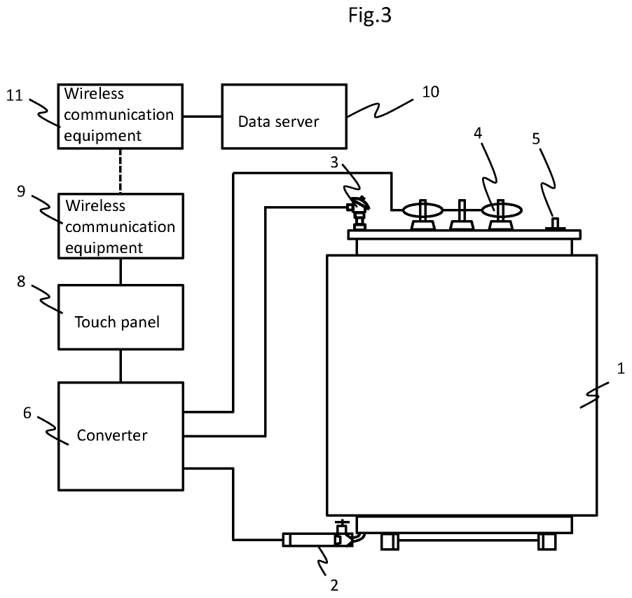

FIG. 3 is a configuration diagram illustrating the transformer and diagnostic system in example 2.

In example 2, the touch panel 8, first wireless communication equipment 9, second wireless communication equipment 11, and data server 10 are provided. The data server 10 can diagnose the abnormalities of the transformer and predict the service life of the transformer via the first wireless communication equipment 9 and second wireless communication equipment 11 without arithmetic PC 7 in example 1. In this example, detection data such as temperature at the top and bottom of the insulating oil, hydrogen, and load current can be stored in the data server 10. Hereinafter, explanations of the same items as in example 1 will be omitted.

The touch panel 8 obtains detection data such as temperature at the top and bottom of the insulating oil, hydrogen, and load current via converter 6. The user can monitor these detection data with the touch panel 8.

First wireless communication equipment 9 and second wireless communication equipment 11 communicate data between touch panel 8 and data server 10.

Based on the detection data from the transformer 1 obtained from the second wireless communication equipment 11, the data server 10 performs the same as the arithmetic PC 7 in example 1 to determine the abnormality of the transformer and to diagnose the remaining life of the transformer.

According to this example, in addition to the effects of example 1, the detection data of multiple transformers can be stored in data server 10, and the diagnosis of each transformer can be centrally managed.

### REFERENCE SIGNS LIST

1: transformer
2: hydrogen detector
3: temperature detector
4: current detector
5: insulated paper pocket
6: converter
7: arithmetic PC
8: touch panel
9: first wireless communication equipment
10: data server
11: second wireless communication equipment

1. to 9. (canceled)

10. A transformer diagnostic system having an insulating oil and a winding comprising:
a detection part detects a temperature at the top and bottom of the insulating oil, an arithmetic unit calculates average oil temperature from the upper part of the insulating oil and the bottom insulating oil,
calculates difference of the average temperature between the winding and the insulating oil from the average temperature of the winding and the average insulating oil and
calculates average temperature of the upper part of the winding from the difference of the average temperature and the temperature of the upper part of the insulating oil.

11. A transformer diagnostic system described in claim 10 comprising:
a current detector detects the load current flowing in the winding,
the arithmetic unit calculates the load factor from the detected load current value.

12. A transformer diagnostic system described in the claim 10 comprising:
a detection unit detects hydrogen,
the arithmetic unit determines an abnormality when the amount of hydrogen detected exceeds predetermined threshold value.

13. A transformer diagnostic system having insulating oil and winding comprising:
a detecting unit detects temperature of top part of the insulating oil, the bottom insulating oil and hydrogen,
an arithmetic unit determine an abnormality based on the detection value from the detection unit,
wherein the arithmetic unit
calculates average oil temperature from the upper and lower insulating oil,
calculates average temperature difference between the winding and the insulating oil from the average winding temperature and the average oil temperature,
calculates average temperature of the upper part of the winding from the average temperature difference and the temperature of upper part of the insulating oil.

14. A transformer diagnostic system described in the claim 13 comprising:
the arithmetic unit calculates a maximum winding point temperature,
estimates the remaining life of the transformer from the calculated maximum winding point temperature.

15. A transformer diagnostic system described in the claim 13 comprising:
the arithmetic unit estimates a maximum winding point temperature from the parameter specified at the time of design.

16. A transformer diagnostic system described in the claim 10 comprising:
an insulating paper pocket,
the arithmetic unit estimates remaining life of the transformer based on the results of analyzing the insulating paper collected from the insulating paper pocket.

17. A transformer diagnostic system described in the claim 10 comprising:
an iron core,
a winding attached to the iron core and insulated by an insulating paper, and an insulating oil for immersing the winding and iron core.

18. A transformer diagnostic system having an insulating oil and a winding comprising:
a communication equipment transmits detected temperature data of the upper and bottom part of the insulation oil,
a data processing unit receives the detected temperature data from the communication equipment,
wherein the data processing unit
calculates an average oil temperature from the temperature of upper and bottom of the insulating oil,
calculates average temperature difference between the winding and the insulating oil from the average winding temperature and the average oil temperature,
calculates upper part temperature of the winding from the average difference of temperature and upper part temperature of the insulating oil.
